(19) United States
(12) Patent Application Publication
(10) Pub. No.: US 2012/0273812 A1
(43) Pub. Date: Nov. 1, 2012

(54) LIGHT SOURCE FOR ILLUMINATION

(76) Inventors: Kenji Takahashi, Osaka (JP); Yuji Hosoda, Osaka (JP); Ryoma Murase, Osaka (JP); Shinji Kadoriku, Osaka (JP); Yusuke Kusaka, Osaka (JP); Kazushige Sugita, Hyogo (JP)

(21) Appl. No.: 13/513,121

(22) PCT Filed: Sep. 30, 2011
(86) PCT No.: PCT/JP2011/005551

§ 371 Date: May 31, 2012

(30) Foreign Application Priority Data
Jan. 14, 2011 (JP) 2011-006411

(51) Int. Cl. H01L 33/60

(52) U.S. Cl. 257/88; 257/E33.072

(57) ABSTRACT

The present invention aims to provide a light source for illumination that achieves excellent luminous intensity distribution and can be easily assembled. A light source 1 comprises a mount 20; a plurality of semiconductor light-emitting elements 12 disposed on an upper surface 22 of the mount 20 so that each light-emitting element emits light primarily upward; and a reflector 80 disposed above the semiconductor light-emitting elements 12 and having a reflective surface 85 configured to reflect a portion of primary light from the light-emitting elements 12 obliquely downward so that the portion of the primary light is prevented from striking the upper surface 22 of the mount 20, wherein the reflector 80 is provided with an opening 86 or a cut for leaking another portion of the primary light upward.

### TECHNICAL FIELD

The present invention relates to light sources for illumination utilizing semiconductor light-emitting elements, and particularly to improvements in luminous intensity distribution.

### BACKGROUND ART

In recent years, bulb-type light sources that utilize semiconductor light-emitting elements such as LEDs (Light Emitting Diode) have been becoming common as alternatives to incandescent light bulbs.

Due to a narrow radiation angle of LEDs, such light sources have a problem that their luminous intensity distribution is narrower than incandescent light bulbs. In view of this problem, a light source 900 disclosed in Patent Literature 1 has a structure as shown in FIG. 20. In this structure, a mount 901 is composed of a first mount member 902 and a second mount member 903. The second mount member 903 protrudes from an area on the upper surface of the first mount member 902 and is in the shape of a frustum. First LEDs 904 are located on the upper surface of the first mount member 902. A second LED 905 is located on the upper surface of the second mount member 903. When the shadow of the second mount member 903 is cast on the upper surface of the first mount member 902, the light-emitting surfaces of the first LEDs 904 are located within the shadow, and the lateral surface of the second mount member 903 serves as light-reflecting surfaces 906. With this structure, the light from the first LEDs 904 is reflected off the light-reflecting surfaces 906 obliquely downward. This supplements the narrow radiation angle, and realizes relatively preferable luminous intensity distribution.

### CITATION LIST

### Patent Literature

[Patent Literature 1] Japanese Patent Application Publication No. 2010-86946

### SUMMARY OF INVENTION

### Technical Problem

In the case of the light source 900 disclosed in Patent Literature 1, however, both the upper surface of the first mount member 902 and the upper surface of the second mount member 903 serve as the mounting surfaces for the LEDs, and the LEDs 904 and 905 are required to be mounted separately on the two mounting surfaces. Hence, assembling work is more complicated than the case where there is only one LED mounting surface. In addition, the complicated shape of the mount 901, composed of the first mount member 902 and the second mount member 903, leads to the increase in cost for the mount 901.

The present invention is made in view of the problems above, and aims to provide a light source that offers excellent luminous intensity distribution and can be assembled easily.

### Solution to Problem

The present invention provides a light source for illumination, comprising: a mount; a plurality of semiconductor light-emitting elements arranged on an upper surface of the mount so that each semiconductor light-emitting element emits light primarily upward; and a reflector located above the semiconductor light-emitting elements and having a reflective surface configured to reflect a portion of primary light from the light-emitting elements obliquely downward so that the portion of the primary light is prevented from striking the upper surface of the mount, wherein the reflector is provided with an opening or a cut for leaking another portion of the primary light upward.

### Advantageous Effects of Invention

The light source for illumination pertaining to the present invention has a structure in which a plurality of semiconductor light-emitting elements are disposed on the upper surface of a mount. Hence, it is easy to place the semiconductor light-emitting elements on the mount, and it is therefore easy to assemble the light source. Also, the reflector located above the semiconductor light-emitting elements has a reflective surface configured to reflect a portion of the primary light from the semiconductor light-emitting elements obliquely downward so that the portion of the primary light is prevented from striking the upper surface of the mount. Hence, the light source achieves excellent luminous intensity distribution even when the radiation angle of the semiconductor light-emitting elements is narrow. Furthermore, since the reflector is provided with an opening or a cut for leaking another portion of the primary light upward, the reflector casts less shadow, and the light source exhibits excellent appearance during the lighting.

### BRIEF DESCRIPTION OF DRAWINGS

FIG. 1 is a partially-cutaway perspective view of a light source pertaining to Embodiment 1.

FIG. 2 is a cross-sectional view taken along the line A-A in FIG. 1, looking in the direction of the appended arrows.

FIG. 3 is an enlarged cross-sectional view showing the portion surrounded by the two-dot chain lines in FIG. 2.

FIG. 4 is a plan view of a semiconductor light-emitting module pertaining to Embodiment 1.

FIG. 5 is a cross-sectional view taken along the line B-B in FIG. 1, looking in the direction of the appended arrows.

FIG. 6 is a luminous intensity distribution curve for explaining the luminous intensity distribution of the light source.

FIG. 7 shows diagrams depicting radiant intensity distribution of a light source during lighting.

FIG. 8 is a partially-cutaway perspective view of a light source pertaining to Embodiment 2.

FIG. 9 is a cross-sectional view showing primary elements of a light source pertaining to Embodiment 2.

FIG. 10 is a partially-cutaway perspective view of a light source pertaining to Embodiment 3.

FIGS. 11A and 11B are diagrams for explaining a light source pertaining to Embodiment 3.

FIG. 12 is a partially-cutaway perspective view of a light source pertaining to Embodiment 4.

FIG. 13 is a cross-sectional view showing primary elements of a light source pertaining to Embodiment 4.

FIG. 14 is a partially-cutaway perspective view of a light source pertaining to Embodiment 5.

FIG. 15 is a cross-sectional view showing primary elements of a light source pertaining to Embodiment 5.

FIG. 16 is an enlarged cross-sectional view showing the portion surrounded by the two-dot chain lines in FIG. 14.

FIGS. 17A and 17B are diagrams for explaining a light source pertaining to Embodiment 6.

FIGS. 18A, 18B and 18C are plan views of semiconductor light-emitting modules pertaining to Modifications.

FIG. 19 is a diagram for explaining light diffusion treatment applied on a globe pertaining to a modification.

FIG. 20 is a cross-sectional view showing a conventional light source.

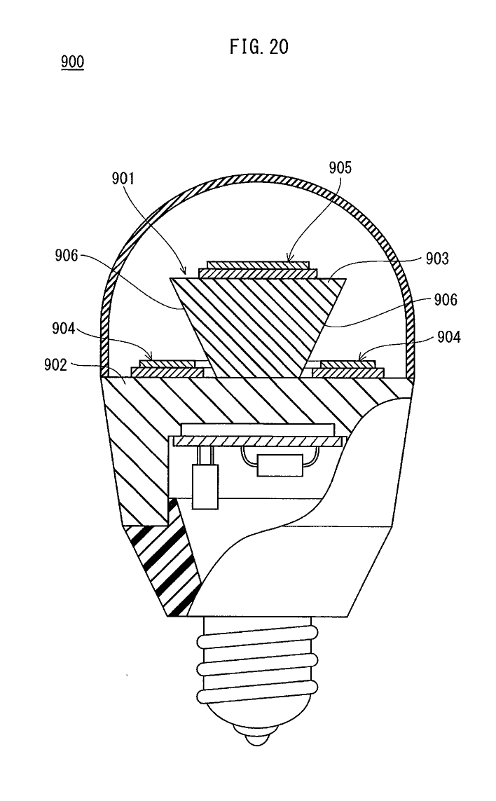

### DESCRIPTION OF EMBODIMENTS

The following describes light sources pertaining to Embodiments of the present invention, with reference to the drawings. Note that the elements shown in the drawings are not drawn to scale. Also note that the sign “-” represents a numerical range, and both ends sandwiching the sign are included in the range.

### Embodiment 1

### [Overall Structure]

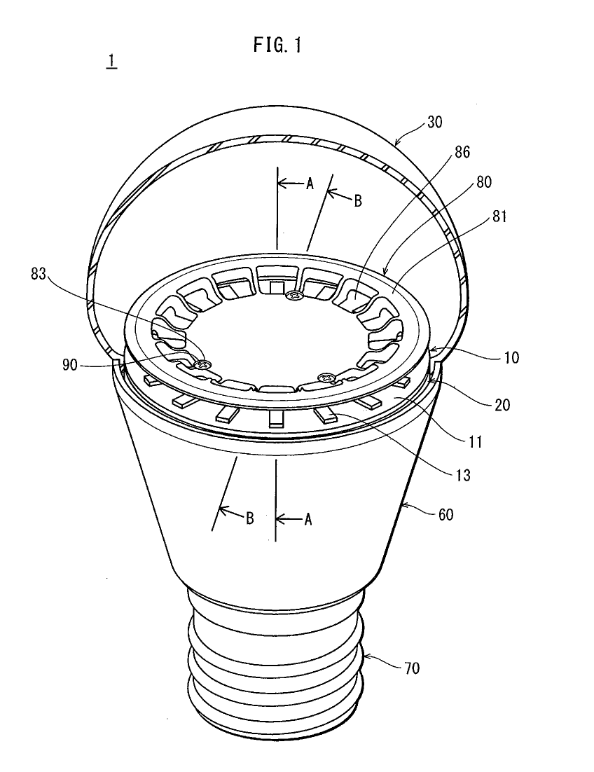

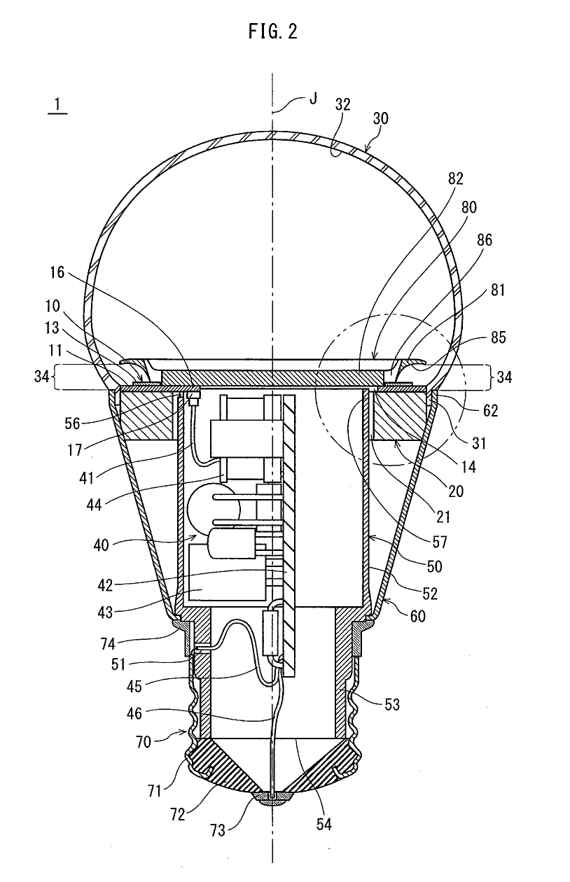

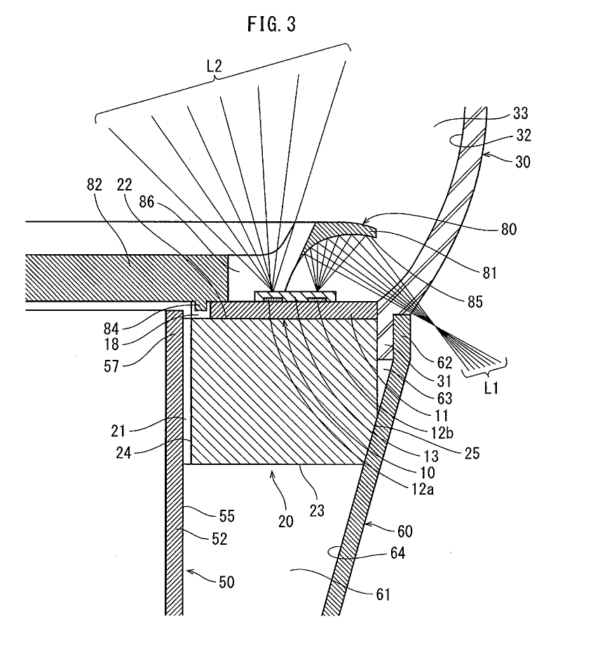

FIG. 1 is a partially-cutaway perspective view of a light source pertaining to Embodiment 1. FIG. 2 is a cross-sectional view taken along the line A-A in FIG. 1, looking in the direction of the appended arrows. FIG. 3 is an enlarged cross-sectional view showing the portion surrounded by the two-dot chain lines in FIG. 2. Note that the dashed-dotted lines extending in the top-to-bottom direction on the drawing sheets each represent a lamp axis J of the light source. The top of the sheet corresponds to the top of the light source, and the bottom of the sheet corresponds to the bottom of the light source.

As shown in FIGS. 1 through 3, a light source 1 pertaining to Embodiment 1 is an LED lamp that serves as a substitute for an incandescent light bulb, and includes: a semiconductor light-emitting module 10 as a light source; a mount 20 on which the semiconductor light-emitting module 10 is mounted; a globe 30 covering the semiconductor light-emitting module 10; a circuit unit 40 for lighting the semiconductor light-emitting module 10; a circuit holder 50 housing the circuit unit 40; a casing 60 enclosing the circuit holder 50; a base 70 electrically connected to the circuit unit 40; and a reflector 80 for diffusing light emitted by the semiconductor light-emitting module 10.

### [Structure of Each Component]

### (1) Semiconductor Light-emitting Module

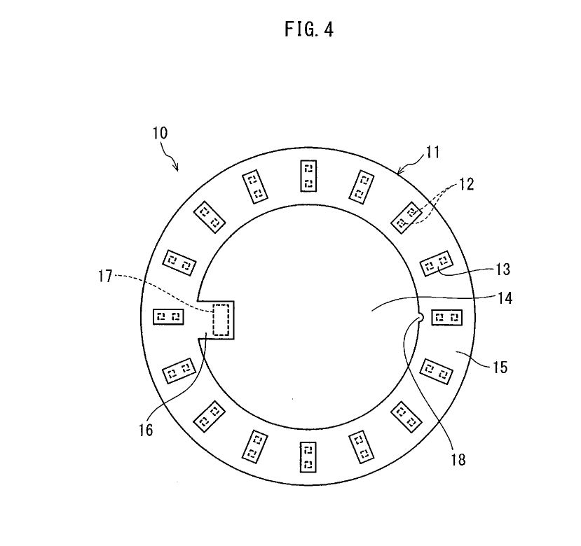

FIG. 4 is a plan view of the semiconductor light-emitting module pertaining to Embodiment 1. As shown in FIG. 4, the semiconductor light-emitting module 10 includes: a mounting board 11; a plurality of semiconductor light-emitting elements 12 serving as a light source mounted on the mounting board 11; and sealants 13 disposed on the mounting board 11 so as to cover the semiconductor light-emitting elements 12. It should be noted here that although the semiconductor light-emitting elements 12 and the semiconductor light-emitting module 10 in the present invention are LEDs and a LED module respectively, LD (laser diode) or EL elements (electric luminescence elements) may be adopted.

The mounting board 11 includes: an element mounting part 15 that is in a substantially annular shape and has a hole 14 that is in a substantially circular shape and is located in the center of the element mounting part 15; and a tongue-shaped part 16 protruding from a portion of an inner periphery of the element mounting part 15 toward the center point of the hole 14. A connector 17, to which a wiring line 41 is to be connected, is provided on the lower surface of the tongue-shaped part 16. With the wiring line 41 connected to the connector 17, the semiconductor light-emitting module 10 and the circuit unit 40 are electrically connected together (See FIG. 2).

Thirty-two semiconductor light-emitting elements 12, for example, are arranged in an annular shape on the upper surface of the element mounting part 15. Specifically, sixteen pairs of two semiconductor light-emitting elements 12, each pair being arranged in the radial direction of the element mounting part 15, are arranged annularly along the peripheral direction of the element mounting part 15 at equal intervals. Note that the term “annular shape” defined in the present application includes a polygonal annular shape, such as a triangle, square, or pentagon shape, as well as a circular ring-like shape. Hence, the semiconductor light-emitting elements 12 may be arranged in an oval annular shape, or a polygonal shape.

Each pair of the semiconductor light-emitting elements 12 is separately sealed with one of the sealants 13 that are in a substantially rectangular-cuboid shape. Hence, the number of the sealants 13 is sixteen. The lengthwise direction of each sealant 13 coincides with the radial direction of the element mounting part 15. When the sealants 13 are viewed in the top-to-bottom direction along the lamp axis J (i.e. in plan view), the sealants 13 are arranged in the radial direction from the lamp axis J as the center point.

The sealants 13 are made mainly of a light-transmissive material. If there is a need for converting the wavelength of the light emitted by the semiconductor light-emitting elements 12 to a predetermined wavelength, a wavelength conversion material for converting the wavelength is mixed in the light-transmissive material. As a light-transmissive material, silicone resin may be used, for example. As a wavelength conversion material, phosphor particles may be used, for example. In the present embodiment, the semiconductor light-emitting elements 12 emit blue light, and the sealants 13 are made of light-transmissive material mixed with phosphor particles for converting blue light to yellow light. A portion of the blue light emitted from the semiconductor light-emitting elements 12 is converted to yellow light by the sealants 13, and thus the semiconductor light-emitting module 10 emits white light generated by mixing blue light not converted and the yellow light resulting from the conversion.

Note that the semiconductor light-emitting module 10 may be a combination of semiconductor light-emitting elements that emit ultraviolet light and phosphor particles that emit three primary colors (red, green, blue), for example. Furthermore, as a wavelength conversion material, a material containing a substance that absorbs light with a particular wavelength and emits light with different wavelength than the absorbed light may be used. Such substances include: a semiconductor; a metal complex compound; an organic dye; and a pigment, for example. The semiconductor light-emitting elements 12 are arranged to emit light primarily upward, i.e., in the direction of the lamp axis J.

### (2) Mount

Returning to FIG. 2, the mount 20 is in a substantially cylindrical shape provided with a through hole 21 that is in a substantially columnar shape, for example. The mount 20 is disposed such that the cylinder axis thereof coincides with the lamp axis J. Hence, the through hole 21 extends in the top-to-bottom direction, and the upper surface 22 and the lower surface 23 of the mount 20 shown in FIG. 3 are faces that are each in a substantially annular shape. The semiconductor light-emitting module 10 is mounted on the upper surface 22 of the mount 20. Thus the semiconductor light-emitting elements 12 are disposed on a same plane so as to emit light primarily upward. Since all the semiconductor light-emitting elements 12 are disposed on a same plane, namely the upper surface 22 of the mount 20, it is easy to mount the semiconductor light-emitting elements 12 on the mount 20, and to assemble the light source.

Note that the upper surface 22 is not necessarily in the substantially annular shape, and may be in any shape. Furthermore, it is not necessary that the upper surface 22 is in a planar shape as a whole if the semiconductor light-emitting elements can be mounted on a same plane. Moreover, the lower surface 23 is not necessarily in a planar shape.

The semiconductor light-emitting module 10, together with the reflector 80, is fixed to the mount 20 with a screw. Note that the semiconductor light-emitting module 10 may be fixed to the mount 20 by, for example, being bonded to or engaged with the mount 20.

The mount 20 is made of metal material, for example. Examples of the metal material include: Al, Ag, Au, Ni, Rh, Pd, an alloy of two or more of them, or an alloy of Cu and Ag. Since such metal material has an excellent thermal conductivity, heat generated by the semiconductor light-emitting module 10 is efficiently conducted to the casing 60.

The light source 1 is lightweight since the through hole 21 is provided in the mount 20. Also, since the circuit unit 40 is partially housed within the through hole 21, or extends off the through hole 21 and is housed within the globe 30, the light source 1 is downsized.

### (3) Globe

Returning to FIG. 2, the globe 30 in the present embodiment is in a shape similar to common A-type bulbs. An open end portion 31 of the globe 30 is pressed into the gap surrounded by an upper end portion 62 of the casing 60. Thus the globe 30 is fixed to the casing 60 so as to cover the semiconductor light-emitting module 10 and the reflector 80. The envelope of the light source 1 consists of the globe 30 and the casing 60.

Note that the globe 30 is not necessarily in the shape similar to A-type bulbs, and may be in any shape. Moreover, the light source globe may be not provided with a globe. Also, the globe 30 may be fixed to the casing 60 by adhesive or the like.

An inner surface 32 of the globe 30 has been subject to light diffusion treatment with the use of silica or white pigment, for example, for diffusing light emitted from the semiconductor light-emitting module 10. The incident light to the inner surface 32 of the globe 30 passes through the globe 30, and is taken out of the globe 30.

### (4) Circuit Unit

The circuit unit 40 is used for lighting the semiconductor light-emitting elements, and includes the circuit board 42 and various kinds of electronic parts 43 and 44 mounted on the circuit board 42. Note that only some of the electronic parts are given reference numbers. The circuit unit 40 is housed in the circuit holder 50, and is fixed to the circuit holder 50 by, for example, being screwed to, bonded to, or engaged with the circuit holder 50.

The circuit board 42 is disposed such that the main surface thereof is in parallel with the lamp axis J. Thus the circuit unit 40 can be compactly housed in the circuit holder 50. On the circuit unit 40, the electronic part 43, which is not resistant to heat, is located close to the lower side, i.e. located away from the semiconductor light-emitting module 10, and the electronic part 44, which is resistant to heat, is located close to the upper side, i.e. located close to the semiconductor light-emitting module 10. With such a structure, the electronic part 43, which is not resistant to heat, is prevented from being broken by heat generated by the semiconductor light-emitting module 10.

The circuit unit 40 and the base 70 are electrically connected by electrical wiring lines 45 and 46. The electrical wiring line 45 passes through the through hole 51 provided in the circuit holder 50, and is connected to a shell 71 of the base 70. The electrical wiring line 46 passes through a lower opening 54 of the circuit holder 50, and is connected to an eyelet 73 of the base 70.

The circuit unit 40 is partially housed within the through hole 21 of the mount 20 or within the globe 30. With this structure, the space below the mount 20 for housing the circuit unit 40 can be downsized. Hence, the distance between the mount 20 and the base 70, and the diameter of the casing 60 can be reduced. This is an advantage in terms of downsizing the light source 1.

### (5) Circuit Holder

The circuit holder 50 is in a substantially cylindrical shape with both ends open, for example, and consists of a large-diameter part 52 and a small-diameter part 53. The large-diameter part 52 as the upper part of the circuit holder 50 houses a large part of the circuit unit 40. On the other hand, the base 70 is fit onto the small-diameter part 53 as the lower part of the circuit holder 50, and thus the opening 54 of the lower opening 54 of the circuit holder 50 is sealed. The circuit holder 50 is preferably made of insulative material, such as resin.

The large-diameter part 52 of the circuit holder 50 ,passes through the through hole 21 of the mount 20, and thus the circuit unit is partially housed in the through hole 21 of the mount 20 while being housed in the circuit holder 50. As shown in FIG. 3, the circuit holder 50 and the mount 20 are not in contact, and a gap is provided between an outer surface 55 of the circuit holder 50 and an inner surface 24 of the through hole 21 of the mount 20. Moreover, the circuit holder 50 is not in contact with the semiconductor light-emitting module 10 or the reflector 80, and a gap is provided between the mounting board 11 of the semiconductor light-emitting module 10 and the outer surface 55 of the circuit holder 50, and between an upper end portion 57 of the circuit holder 50 and the reflector 80. Hence, heat generated by the semiconductor light-emitting module 10 is not easily conducted to the circuit holder 50, and hardly raises the temperature of the circuit holder 50. Thus, the circuit unit 40 is prevented from being damaged by heat.

Returning to FIG. 2, the circuit holder 50 is provided with a through hole 56, which corresponds in location to the tongue-shaped part 16 of the semiconductor light-emitting module 10. The tip of the tongue-shaped part 16 is inserted into the circuit holder 50 via the through hole 56. The connector 17 disposed on the tongue-shaped part 16 is located within the circuit holder 50.

### (6) Casing

The casing 60 is, for example, in a cylindrical shape with both ends open, and the diameter thereof is gradually reduced in from the top to the bottom. As shown in FIG. 3, an upper end portion 62 of the casing 60 houses therein the mount 20 and the open end portion 31 of the globe 30. The casing 60 is fixed to the mount 20 by swaging, for example. Note that the casing 60 may be fixed to the mount 20 by pouring adhesive into a space 63 surrounded by the casing 60, the mount 20 and the globe 30.

The outer periphery of the lower end portion of the mount 20 is tapered in accordance with the shape of an inner circumferential surface 64 of the casing 60. A taper surface 25 of the mount 20 is in contact with the inner circumferential surface 64 of the casing 60 by surface contact. Hence the heat conducted from the semiconductor light-emitting module 10 to the mount 20 is easily conducted further to the casing 60. Heat generated by the semiconductor light-emitting elements 12 is mainly conducted to the base 70 via the mount 20 and the casing 60, and further via the small-diameter part 53 of the circuit holder 50. Then the heat is radiated from the base 70 to the light fixture (not illustrated).

The casing 60 is made of metal material, for example. Examples of the metal material include: Al, Ag, Au, Ni, Rh, Pd, an alloy of two or more of them, or an alloy of Cu and Ag. Since such metal material has an excellent thermal conductivity, heat conducted to the casing 60 is efficiently conducted to the base 70. Note that the casing 60 is not necessarily made of metal, and may be made of material with high thermal conductivity, such as resin.

### (7) Base

Returning to FIG. 2, the base 70 is a member for receiving electric power from the socket of the light fixture when the light source 1 is attached to the light fixture and is lit up. Although the base 70 is not limited to any particular type, an E26 base, which is a base of an Edison type, is used in the present embodiment. The base 70 includes: a shell 71 having a substantially circular cylinder and whose outer surface has an external thread; and an eyelet 73 attached to the shell 71 with an insulator 72 therebetween. An insulator 74 is inserted between the shell 71 and the casing 60.

### (8) Reflector

The reflector 80 is in a tubular shape with a bottom, and includes: a main body 81 that is in a cylindrical shape with both ends open; and an attachment 82 that is in a substantially discoid shape and seals the lower opening of the main body 81. The reflector 80 is made of, for example, resin such as polycarbonate, metal such as aluminum, glass, ceramics, or the like. In the present embodiment, polycarbonate is used. Since resin such as polycarbonate is lightweight, using resin is preferable for reducing the weight of the light source 1.

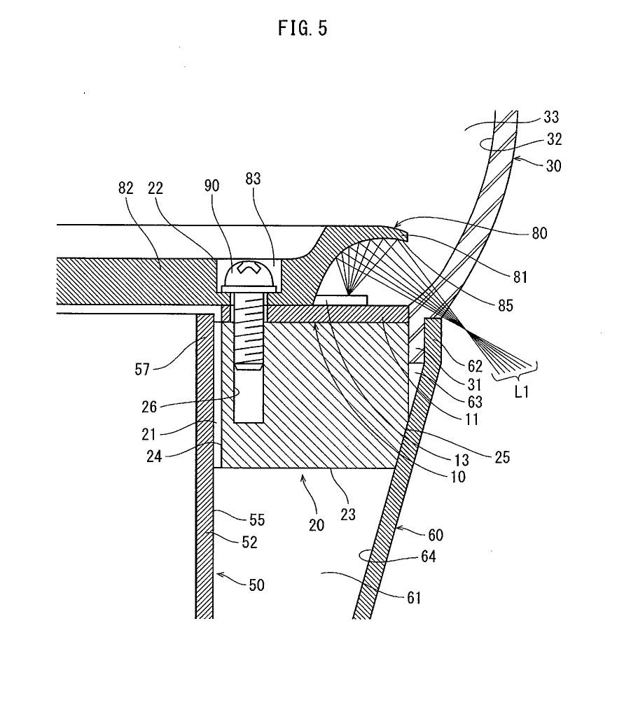

FIG. 5 is a cross-sectional view taken along the line B-B in FIG. 1, looking in the direction of the appended arrows. As shown in FIG. 5, the reflector 80 is provided with a hole 83. The reflector 80, together with the mounting board 11, is fixed to the mount 20 by placing the outer periphery of the attachment 82 on the inner periphery of the mounting board 11 of the semiconductor light-emitting module 10 and then screwing a screw 90, inserted in the hole 83, into a screw hole 26 of the mount 20. As shown in FIG. 1, the same structure as the hole 83 is provided at three points near the border between the main body 81 and the attachment 82, for example.

As shown in FIG. 4, the inner periphery of the element mounting part 15 of the mounting board 11 is partially cut out to form a cut 18. Also, as shown in FIG. 3, the lower surface of the attachment 82 is provided with a protrusion 84. With the use of the cut 18 and the protrusion 84, it is easy to appropriately position the reflector 80 with respect to the semiconductor light-emitting elements 12 by simply fitting the protrusion 84 to the cut 18.

The main body 81 is in a substantially cylindrical shape, and whose outside diameter gradually increases from bottom to top. The main body 81 is disposed above the semiconductor light-emitting elements 12, with a gap between the main body 81 and the semiconductor light-emitting module 10, such that the cylinder axis of the main body 81 intersects with the upper surface 22 of the mount 20 at right angles. The outer surface 85 of the main body 81 is in a substantially annular shape when viewed in the bottom-to-top direction along the lamp axis J. The outer surface 85 covers the semiconductor light-emitting elements 12 arranged annularly on the mounting board 11, and thus faces the semiconductor light-emitting elements 12.

The reflector 80 is provided with a plurality of openings 86, which are arranged across the main body 81 and the attachment 82 at intervals, along the circumference of the outer surface 85 of the main body 81 around the axis of the main body 81. Specifically, the same number of openings 86 as the sealant 13 of the semiconductor light-emitting module 10, namely sixteen openings 86 are arranged on the main body 81 at intervals along the circumference of the outer surface 85 so that the openings 86 face the sealants 13 in one-to-one correspondence.

Although the openings 86 in the present embodiment are through holes and no parts are fit into the openings 86, the openings 86 do not necessarily have such a structure if light can be leaked upward. For example, a light-transmissive member may be fit into some or all of the openings 86 so that light is allowed to leak upward after passing through the light-transmissive member. Also, the number of the openings 86 is not necessarily the same as the number of the sealants 13. The number of the openings 86 may be greater or smaller than the number of the sealants 13, and may be single or plural.

In plan view, the opening 86 is in a substantially square shape, and approximately a half of the sealant 13 closer to the cylinder axis is located within the opening 86. The other half farther to the cylinder axis faces the outer surface 85 of the main body 81. In other words, approximately a half of the sealant 13 can be seen from above the opening 86, and the other half is hidden behind the main body 81. This can be explained as follows, based on the relationship with the semiconductor light-emitting elements 12. Among two semiconductor light-emitting elements 12 sealed with a single sealant 13, the semiconductor light-emitting element 12a closer to the cylinder axis is located within the opening 86, and the semiconductor light-emitting element 12b farther from the cylinder axis faces the outer surface 85 of the main body 81.

The semiconductor light-emitting element 12b emits light primarily toward the outer surface 85, and the outer surface 85 serves as the reflective surface of the reflector 80. In the present embodiment, the reflector 80 is made of white polycarbonate in order to increase the reflectivity of the outer surface 85. It is preferable to form the main body 81 from a white material for increasing the reflectivity of the outer surface 85. Another approach to increase the reflectivity of the outer surface 85 is to process the outer surface 85 of the main body 81 to be reflective. For example, grinding, coating, thermal deposition, electron beam deposition, sputtering, plating, or the like may be adopted to increase the reflectivity.

The outer surface 85 of the main body 81 is a concavity curving toward the cylinder axis of the main body 81. More specifically, in the cross section (hereinafter referred to as “vertical cross section”) of the main body 81 along an imaginary plane including the lamp axis J (which coincides with the cylinder axis), the outer surface 85 is in a substantially arc-like shape curving toward the lamp axis J. In other words, the arc is a concavity curved so as to be closer to the lamp axis J with respect to the line segment connecting the lower edge and the upper edge of the outer surface 85 in the cross section. Specifically, in the present embodiment, the outer surface 85 in the vertical cross section is in a substantially elliptical arc-like shape.

The concave shape curving toward the cylinder axis is suitable for reflecting light from the semiconductor light-emitting elements 12 in an obliquely downward direction that is closer to the right downward direction (i.e. closer to the parallel direction to the lamp axis J). Thus, this shape effectively widens the light distribution angle of the light source 1. Also, such a shape is suitable for concentrating the reflection light toward a particular direction.

In the present embodiment, the outer surface 85 of the main body 81 entirely serves as the reflective surface. However, this is not essential, and it is possible that only a part of the outer surface 85 serves as the reflective surface.

Also, the shape of the outer surface 85 of the main body 81 of the reflector 80 is not limited to a substantially arc-like shape curving toward the lamp axis J in the vertical cross section. The outer surface 85 may be in a substantially arc-like shape curving away from the lamp axis J, or may be straight in the vertical cross section.

Also, although the reflector 80 of the present embodiment is in a cylindrical shape with a bottom, the reflector may be in a substantially plate-like shape.

As represented as optical paths L1 in FIG. 3, a large portion of the light emitted from the semiconductor light-emitting element 12b strikes the outer surface 85 of the main body 81 and is reflected off the outer surface 85. The reflection light passes through the annular area laterally surrounding the mount 20, and travels obliquely downward so as to avoid the upper surface 22 of the mount 20. Meanwhile, as represented as optical paths L2 in FIG. 3, a large portion of the light emitted from the semiconductor light-emitting element 12a passes through the opening 86, and leaks upward. Here, note that not all the light emitted from the semiconductor light-emitting element 12b is reflected off the outer surface 85 obliquely downward. A portion of the light passes through the opening 86 and leaks upward. Also, not all the light emitted from the semiconductor light-emitting element 12a passes through the opening 86 and leaks upward. A portion of the light is reflected off the outer surface 85 obliquely downward so as to avoid the upper surface 22 of the mount 20.

As described above, the reflector 80 achieves the function of diffusing the light emitted by the semiconductor light-emitting elements 12.

Since the light source 1 has the outer surface 85 for reflecting a portion of the light from the semiconductor light-emitting elements 12 obliquely downward so as to avoid the upper surface 22 of the mount 20, the light source 1 achieves excellent luminous intensity distribution even when the semiconductor light-emitting elements 12 have a narrow radiation angle. Also, since the semiconductor light-emitting elements 12 are arranged annularly, and accordingly, the outer surface 85 is arranged annularly, the reflection, by which the light is reflected obliquely downward so as to avoid the upper surface 22, occurs all around the mount 20. Hence, the light source 1 achieves excellent luminous intensity distribution all around the lamp axis J.

[Luminous Intensity Distribution of Light source]

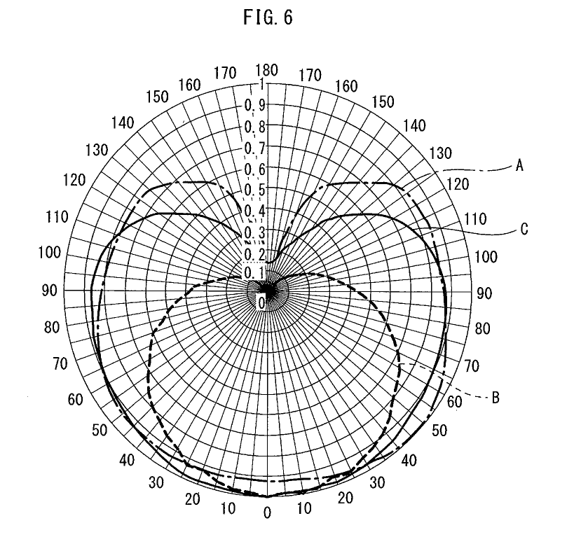

The following describes in detail the reason why the light source 1 achieves previous luminous intensity distribution. FIG. 6 is a luminous intensity distribution curve for explaining the luminous intensity distribution of the light source. As shown in FIG. 6, the luminous intensity distribution curve represents 360-degree luminous intensities including the upward direction of the light source 1. The upward direction long the lamp axis J of the light source 1 is marked with 0°, the downward direction along the lamp axis J is marked with 180°, and the entire circumference is marked every 10°, in both clockwise and counter clockwise directions. In the luminous intensity curve, the scale marks given in the radial direction indicate values of luminous intensity. Each intensity value is represented as relative magnitude, with respect to the maximum intensity of the luminous intensity curve when the value of the maximum intensity is 1.

In FIG. 6: the dashed-dotted line represents a luminous intensity distribution curve A of an incandescent light bulb; the broken line represents a luminous intensity distribution curve B of the light source 900 of the Patent Literature 1; and the solid line represents a luminous intensity distribution curve C of the light source 1 pertaining to the present embodiment.

The luminous intensity distribution was evaluated based on the light distribution angle. A light distribution angle represents an angular range within which the emitted light has luminous intensity of more than a half of the maximum luminous intensity of the light source. In the case of the luminous intensity distribution curve shown in FIG. 6, the light distribution angle represents an angular range within which the relative luminous intensity is equal to or greater than 0.5.

As seen from FIG. 6, the light distribution angle of the incandescent light bulb is approximately 315°, the light distribution angle of the light source 900 of the Patent Literature 1 is approximately 165°, and the light distribution angle of the light source 1 pertaining to the present embodiment is approximately 270°. Thus, the light distribution angle of the light source 1 is wider than the light source 900, and is close to the incandescent light bulb. This means that the luminous intensity distribution of the light source 1 is better than the light source 900, and is close to the incandescent light bulb.

To improve the light distribution angle of the light source 1, the semiconductor light-emitting elements 12 may be mounted on the outer periphery of the element mounting part 15 of the mounting board 11. With this structure, the reflector 80 reflects the light emitted from the semiconductor light-emitting elements 12 in an obliquely downward direction that is closer to the right downward direction (i.e. closer to the parallel direction to the lamp axis J).

### [Excellent Appearance of Light Source While Being Lit]

The following describes the excellent appearance of the light source 1 while being lit. Since the openings 86 are provided in the reflector 80, the light source 1 produces preferable effects while being lit. From the openings 86, the main body 81 of the reflector 80 leaks upward a portion of the light emitted by the semiconductor light-emitting elements 12 as well as reflecting the light. Hence, the reflector 80 casts less shadow, and when viewed from above or from a side (i.e. in the direction perpendicular to the lamp axis J), the appearance of the light source 1 being lit is preferable.

To confirm the excellent appearance during the lighting, the radiant intensity distribution of the light source 1 pertaining to the present embodiment was compared with the radiant intensity distribution of a light source pertaining to a comparative example with a reflector that is provided with no openings. Note that the light source pertaining to the comparative example has the same structure as the light source 1 pertaining to the present embodiment except that the reflector is provided with no openings.

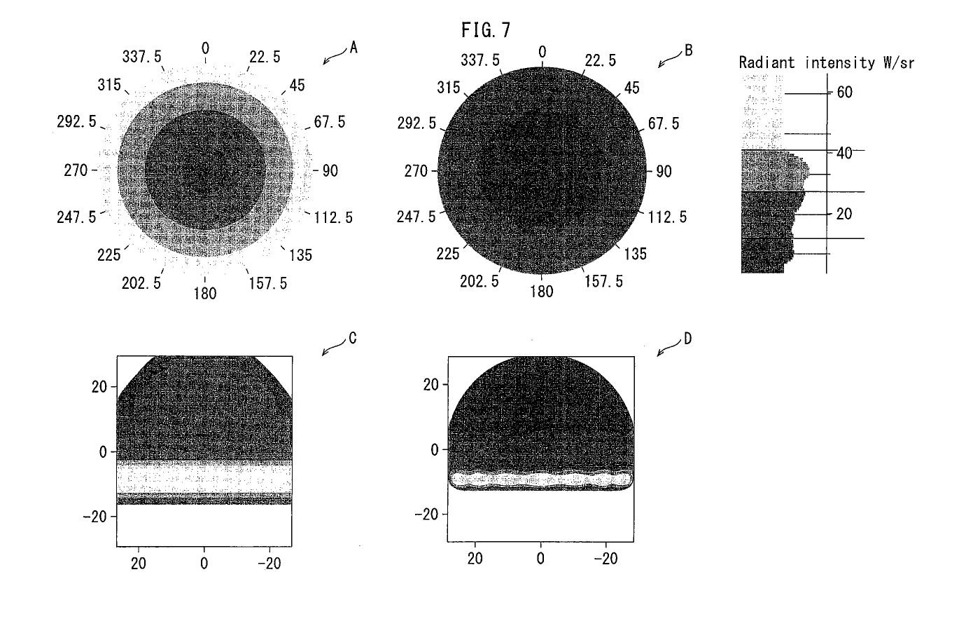

FIG. 7 shows diagrams depicting radiant intensity distribution of a light source during lighting. The diagram A shows the case where the light source pertaining to the present embodiment is viewed from above (i.e. in plan view). The diagram B shows the case where the light source pertaining to the comparative example is viewed from above. The diagram C shows the case where the light source pertaining to the present embodiment is viewed from a side (i.e. in the direction perpendicular to the lamp axis J). The diagram D shows the case where the light source pertaining to the comparative example is viewed from a side.

Comparing A and B shows that the reflector 80 of the light source 1 pertaining to the present embodiment, which is provided with the openings 86, casts less shadow over the center portion of the globe 30 than the reflector of the light source pertaining to the comparative example, which is provided with no openings. Also, comparing C and D shows that the reflector of the light source 1 pertaining to the present embodiment casts less shadow over the top portion (upper portion) of the globe 30 than the reflector of the light source pertaining to the comparative example when viewed from their respective sides. As described above, since the reflector casts less shadow, the light source 1 exhibits excellent appearance during the lighting.

### Embodiment 2

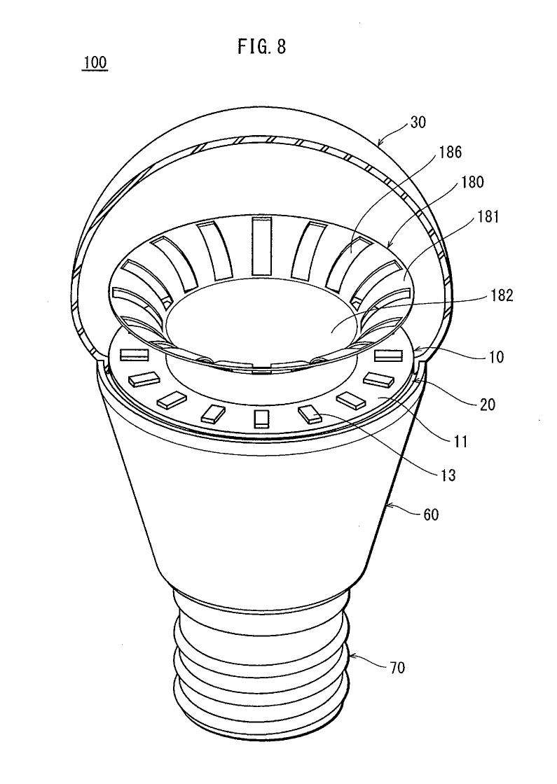

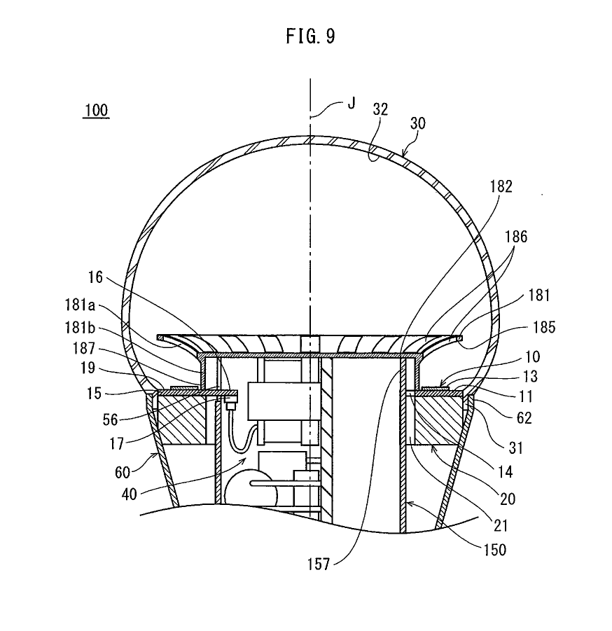

FIG. 8 is a partially-cutaway perspective view of a light source pertaining to Embodiment 2. FIG. 9 is a cross-sectional view showing primary elements of a light source pertaining to Embodiment 2. As shown in FIG. 8 and FIG. 9, a light source 100 pertaining to Embodiment 2 is greatly different from the light source 1 pertaining to Embodiment 1 in the shape of openings 186 of a main body 181. The other components are basically the same as the light source 1 pertaining to Embodiment 1. Therefore, the following describes only the differences in detail, and the explanations of the other components are simplified or omitted. The same components as Embodiment 1 are given the same reference numbers as Embodiment 1.

A light source 100 pertaining to Embodiment 2 is an LED lamp that serves as a substitute for an incandescent light bulb, and includes: a semiconductor light-emitting module 10; a mount 20; a globe 30; a circuit unit 40; a circuit holder 50; a casing 60; a base (not depicted); and a reflector 180 for diffusing light emitted by the semiconductor light-emitting module 10.

The circuit holder 150 is substantially the same as the circuit holder 50 pertaining to Embodiment 1 except that within the globe 30, the upper end portion 157 protrudes more than in Embodiment 1. Since the upper end portion 157 of the circuit holder 150 protrudes more within the globe 30, the space for housing the circuit unit 40 is larger than Embodiment 1.

The main body 181 of the reflector 180 is in a substantially cylindrical shape that is similar to the shape of the main body 81 of the reflector 80 pertaining to Embodiment 1 with the lower end portion of the main body 81 extended downward along the lamp axis J. The diameter of the upper end portion of the main body 181 gradually increases from bottom to top, and the diameter (the outside diameter and the inside diameter) of the lower end portion of the main body 181 is constant. The lower end portion 187 of the main body 181 is fixed to the upper surface 19 of the element mounting part 15 of the mounting board 11.

The attachment 182 of the reflector 180 is in a substantially disc-like shape, and is located at the border between the part 181a with a gradually increasing diameter and the part 181b with a constant diameter of the main body 181, so that the main body 181 is partitioned with the attachment 182. The attachment 182 is attached to the upper end portion 157 of the circuit holder 150.

The part 181a of the main body 181, whose diameter gradually increases, is provided with openings 186 elongated in the direction perpendicular to the cylinder axis of the main body 181. The openings 186 are arranged radially with respect to the cylinder axis. Specifically, in plan view, each of the openings 186 is in a substantially rectangular shape whose lengthwise direction is perpendicular to the lamp axis J. Each sealant 13 of the semiconductor light-emitting module 10 is entirely located within the corresponding opening 186 (i.e. can be seen from above the opening 186). This structure increases the ratio of the portion of light that travels upward.

Note that it is possible to increase the ratio of the portion of light that travels obliquely downward by displacing the openings 186 to reduce the amount of the sealants 13 that can be seen from the openings 186 in plan view. The openings 186 may be located so that the sealants 13 are entirely hidden behind the main body 181.

The number of the openings 186 is not necessarily the same as the number of the sealants 13. The number of the openings 186 may be greater or smaller than the number of the sealants 13, and may be single or plural. The width of each of the openings 186 in the widthwise direction (the circumferential direction of the main body 181) may be uniform all along the lengthwise direction (the direction perpendicular to the lamp axis J), or may increase as the distance from the lamp axis J increases, or may decrease as the distance from the lamp axis J increases.

The outer surface 185 of the main body 181 entirely serves as a reflective surface. In the present embodiment, the outer surface 185 of the main body 181 entirely serves as the reflective surface. However, this is not essential, and it is possible that only a part of the outer surface 185 serves as the reflective surface.

Since the outer surface 185 reflects a portion of the light from the semiconductor light-emitting module. 10 obliquely downward so as to avoid the upper surface 22 of the mount 20, the light source 100 achieves excellent luminous intensity distribution even when the semiconductor light-emitting elements 12 have a narrow radiation angle. Moreover, since another portion of the light emitted by the semiconductor light-emitting module 10 passes through the openings 186 and leaks upward, the light source 100 exhibits excellent appearance during the lighting.

### Embodiment 3

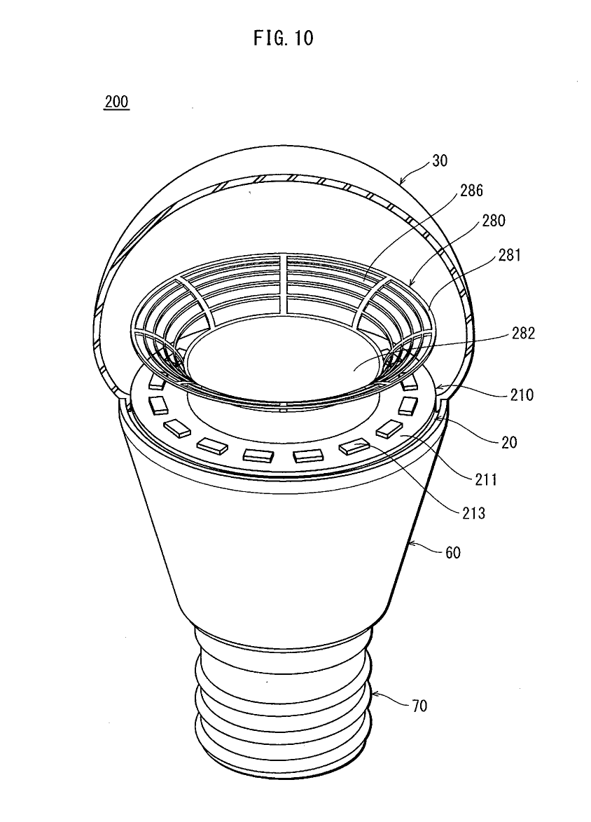

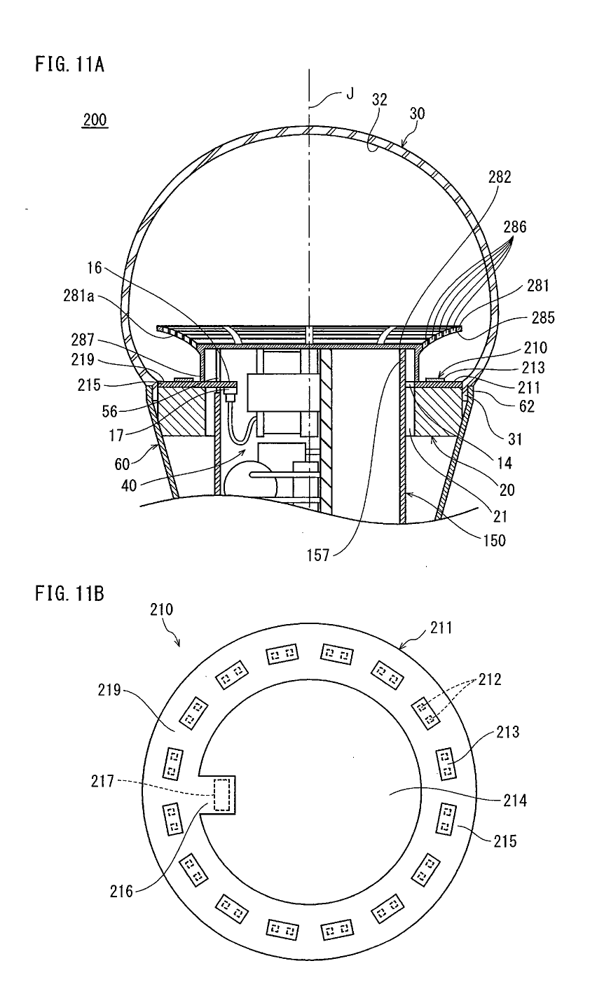

FIG. 10 is a partially-cutaway perspective view of a light source pertaining to Embodiment 3. FIGS. 11A and 11B are diagrams for explaining a light source pertaining to Embodiment 3. FIG. 11A is a cross-sectional view showing primary elements of the light source, and FIG. 11B is a plan view showing a semiconductor light-emitting module. As shown in FIG. 10 and FIG. 11A, a light source 200 pertaining to Embodiment 3 is greatly different from the light source 100 pertaining to Embodiment 2 in regard to the shape of openings 286 of a main body 281 and arrangement of semiconductor light-emitting elements 212. The other components are basically the same as the light source 100 pertaining to Embodiment 2. Therefore, the following describes only the differences in detail, and the explanations of the other components are simplified or omitted. The same components as the embodiments described above are given the same reference numbers as the embodiments.

The light source 200 pertaining to Embodiment 3 is an LED lamp that serves as a substitute for an incandescent light bulb, and includes: a semiconductor light-emitting module 210 as a light source; a mount 20 on which the semiconductor light-emitting module 210 is mounted; a globe 30 covering the semiconductor light-emitting module 210; a circuit unit 40 for lighting the semiconductor light-emitting module 210; a circuit holder 150 housing the circuit unit 40; a casing 60 enclosing the circuit holder 150; a base (not depicted) electrically connected to the circuit unit 40; and a reflector 280 for diffusing light emitted by the semiconductor light-emitting module 210.

As shown in FIG. 11B, in the semiconductor light-emitting module 210, the sealants 213 are arranged on the element mounting part 215 of the mounting board 211 so that the long sides of the sealants 213 form a ring aligned along the circumference of the element mounting part 215. A plurality of semiconductor light-emitting elements 212 are arranged on the element mounting part 215 of the mounting board 211 along the circumference of the element mounting part 215. Pairs of two semiconductor light-emitting elements 212 are sealed with sealants 213, and the long sides of the sealants 213 form a ring aligned along the circumference of the element mounting part 215. With such a structure, the arrangement of the parts that emit light is more close to consecutive arrangement along the circumference of the element mounting part 215, and the unevenness in the luminance in the circumferential direction hardly occurs.

Note that a tongue-shaped part 216 is provided to extend from a portion of the inner periphery of the element mounting part 215 toward the center point of the hole 214, and a connector 217 is provided on the lower surface of the tongue-shaped part 216.

Returning to FIG. 11A, in regard to the reflector 280, the main body 281 and the attachment 282 are respectively in the same shapes as the main body 181 and the attachment 182 of the reflector 180 pertaining to Embodiment 2. Similarly to Embodiment 2, the lower end portion 287 of the main body 281 is fixed to the upper surface 219 of the element mounting part 215 of the mounting board 211, and the attachment 182 is fixed to the upper end portion 157 of the circuit holder 150.

The part 281a of the main body 281, whose diameter gradually increases from bottom to top, is provided with openings 286 elongated in the circumferential direction of the main body 281. The openings 286 are arranged concentrically around the cylinder axis. Specifically, each of the openings 286 is a slit that is in the shape of one of eight arcs equally divided from a ring. Five sets of eight separate arc-like slits are arranged concentrically around the cylinder axis. In plan view, the sealant 213 of the semiconductor light-emitting module 210 is partially located within the opening 286 (i.e. can be partially seen from above the opening 286). With such a structure, it is almost unnecessary to correct positioning of the openings 286 and the sealants 213 in the circumferential direction. Hence, it is easy to assemble the light source 200.

The openings 286 are not limited to those described above in regard to the shape, the size, the number and the arrangement. However, in order to make it almost unnecessary to correct positioning of the openings 286 and the sealants 213 in the circumferential direction, it is preferable that a plurality of arc-like openings 286 or a single ring-like opening, each serving as a slit, is provided along the circumference of the main body 281.

The outer surface 285 of the main body 281 entirely serves as a reflective surface. In the present embodiment, the outer surface 285 of the main body 281 entirely serves as the reflective surface. However, this is not essential, and it is possible that only a part of the outer surface 285 serves as the reflective surface.

Since the outer surface 285 reflects a portion of the light from the semiconductor light-emitting module 210 obliquely downward so as to avoid the upper surface 22 of the mount 20, the light source 200 achieves excellent luminous intensity distribution even when the semiconductor light-emitting elements 212 have a narrow radiation angle. Moreover, since another portion of the light emitted by the semiconductor light-emitting module 210 passes through the openings 286 and leaks upward, the light source 200 exhibits excellent appearance during the lighting.

### Embodiment 4

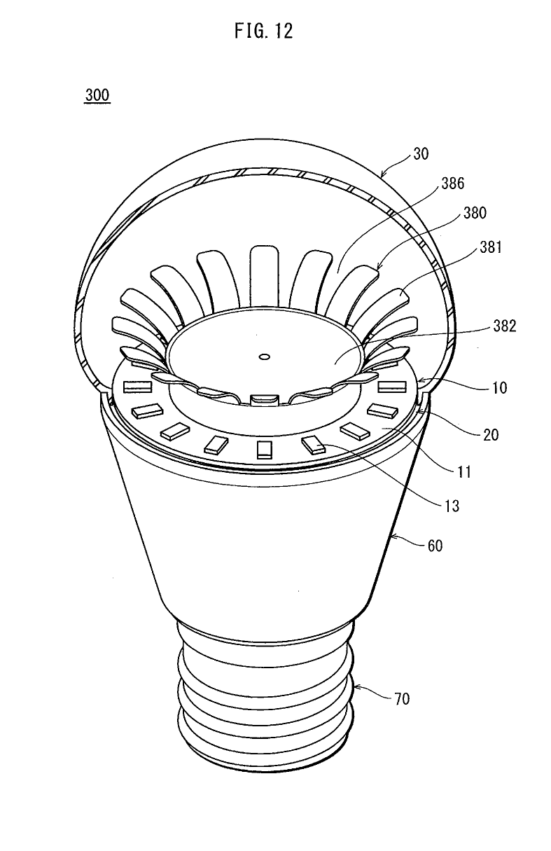

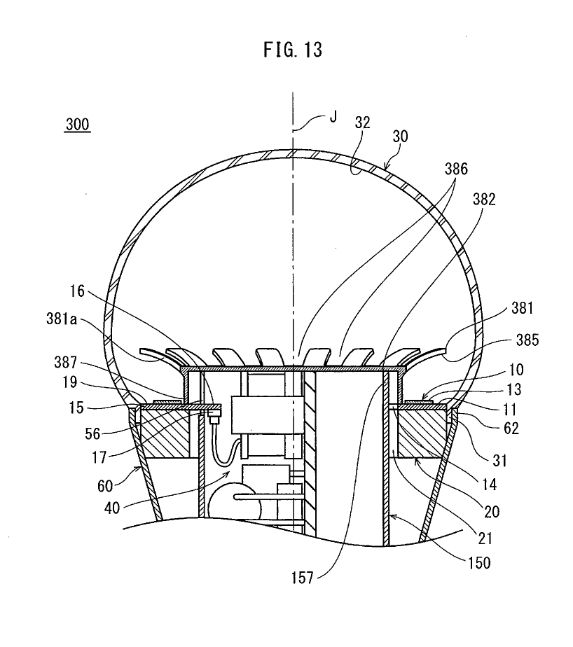

FIG. 12 is a partially-cutaway perspective view of a light source pertaining to Embodiment 4. FIG. 13 is a cross-sectional view showing primary elements of a light source pertaining to Embodiment 4. As shown in FIG. 12 and FIG. 13, a light source 300 pertaining to Embodiment 4 is different from the light source 100 pertaining to Embodiment 2 in that the reflector 380 of the light source 300 is provided with cuts 386 instead of openings. The other components are basically the same as the light source 100 pertaining to Embodiment 2. Therefore, the following describes only the differences in detail, and the explanations of the other components are simplified or omitted. The same components as Embodiment 2 are given the same reference numbers as Embodiment 2.

A light source 300 pertaining to Embodiment 4 is an LED lamp that serves as a substitute for an incandescent light bulb, and includes: a semiconductor light-emitting module 10; a mount 20; a globe 30; a circuit unit 40; a circuit holder 150; a casing 60; a base (not depicted); and a reflector 380 for diffusing light emitted by the semiconductor light-emitting module 10.

In regard to the reflector 380, the main body 381 and the attachment 382 are respectively in the same shapes as the main body 181 and the attachment 182 of the reflector 180 pertaining to Embodiment 2. Similarly to Embodiment 2, the lower end portion 387 of the main body 381 is fixed to the upper surface 19 of the element mounting part 15 of the mounting board 11, and the attachment 382 is fixed to the upper end portion 157 of the circuit holder 150.

The part 381a of the main body 381, whose diameter gradually increases from bottom to top, is provided with cuts 386. The cuts 386 are each in a rectangular shape whose lengthwise direction is perpendicular to the cylinder axis of the main body 381, and are arranged radially with respect to the cylinder axis of the main body 381. Specifically, in plan view, each of the cuts 386 is in a substantially rectangular shape whose lengthwise direction is perpendicular to the lamp axis J. Each sealant 13 of the semiconductor light-emitting module 10 is entirely located within the corresponding cut 386 (i.e. can be seen from above the cut 386). This structure increases the ratio of the portion of light that travels upward.

Note that it is possible to increase the ratio of the portion of light that travels obliquely downward by displacing the cuts 386 to reduce the amount of the sealants 13 that can be seen from the cuts 386 in plan view. The cuts 386 may be located so that the sealants 13 are entirely hidden behind the main body 381.

Although the cuts 386 in the present embodiment are through holes and no parts are fit into the cuts 386, the cuts 386 do not necessarily have such a structure if light can be leaked upward. For example, a light-transmissive member may be fit into some or all of the cuts 386 so that light is allowed to leak upward after passing through the light-transmissive member.

Although the cuts 386 of the present embodiment are left as they are and no parts are fit into the cuts 386, the cuts 386 do not necessarily have such a structure if light can be leaked upward. For example, a light-transmissive member may be fit into some or all of the cuts 386 so that light is allowed to leak upward after passing through the light-transmissive member. The number of the cuts 386 is not necessarily the same as the number of the sealants 13. The number of the cuts 386 may be greater or smaller than the number of the sealants 13, and may be single or plural. The width of each of the cuts 386 in the widthwise direction (the circumferential direction of the main body 381) may be uniform all along the lengthwise direction (the direction perpendicular to the lamp axis J), or may increase as the distance from the lamp axis J increases, or may decrease as the distance from the lamp axis J increases.

The outer surface 385 of the main body 381 entirely serves as a reflective surface. In the present embodiment, the outer surface 385 of the main body 381 entirely serves as the reflective surface. However, this is not essential, and it is possible that only a part of the outer surface 385 serves as the reflective surface.

Since the outer surface 385 reflects a portion of the light from the semiconductor light-emitting module 10 obliquely downward so as to avoid the upper surface 22 of the mount 20, the light source 300 achieves excellent luminous intensity distribution even when the semiconductor light-emitting elements 12 have a narrow radiation angle. Moreover, since another portion of the light emitted by the semiconductor light-emitting module 10 passes through the cuts 386 and leaks upward, the light source 300 exhibits excellent appearance during the lighting.

### Embodiment 5

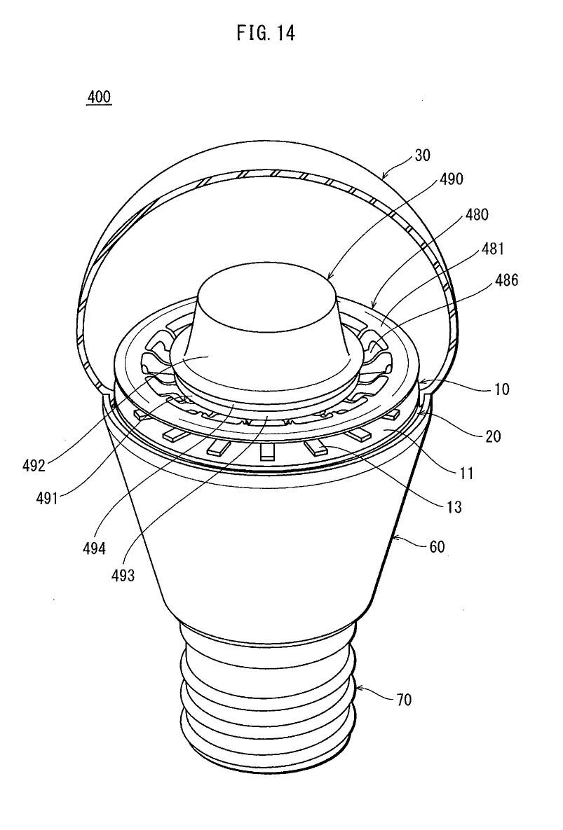

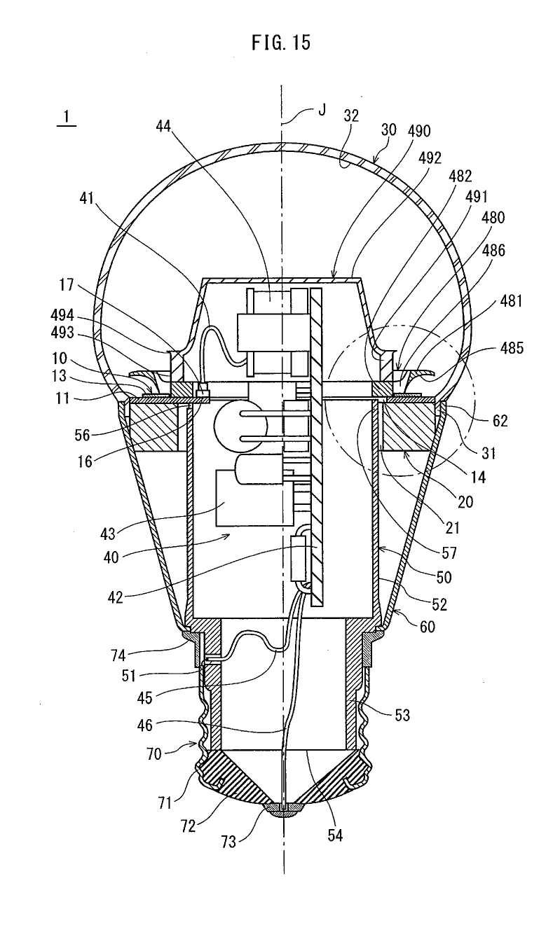

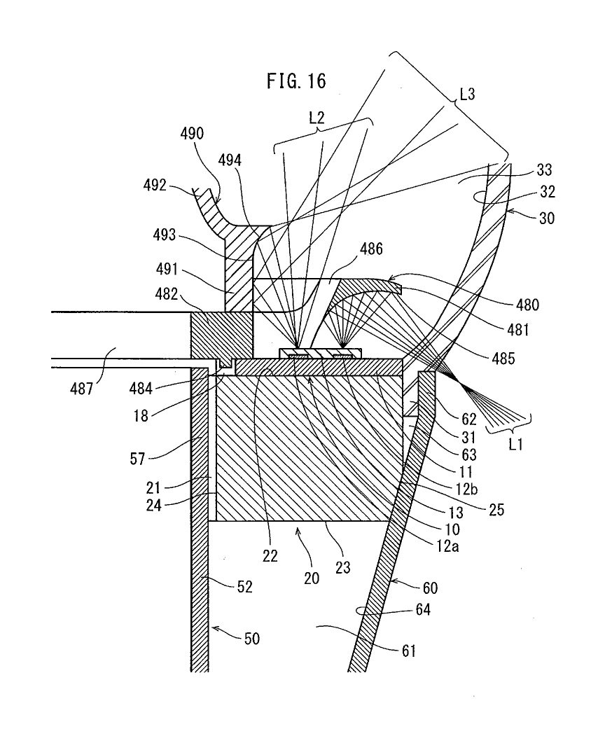

FIG. 14 is a partially-cutaway perspective view of a light source pertaining to Embodiment 5. FIG. 15 is a cross-sectional view showing primary elements of a light source pertaining to Embodiment 5. FIG. 16 is an enlarged cross-sectional view showing the portion surrounded by the two-dot chain lines in FIG. 15. As shown in FIG. 14 and FIG. 15, a light source 400 pertaining to Embodiment 5 is greatly different from the light source 1 pertaining to Embodiment 1 in that the light source 400 is provided with a secondary reflector that reflects a portion of the light that has passed through the openings 486. The other components are basically the same as the light source 1 pertaining to Embodiment 1. Therefore, the following describes only the differences in detail, and the explanations of the other components are simplified or omitted. The same components as Embodiment 1 are given the same reference numbers as Embodiment 1.

A light source 400 pertaining to Embodiment 5 is an LED lamp that serves as a substitute for an incandescent light bulb, and includes: a semiconductor light-emitting module 10; a mount 20; a globe 30; a circuit unit 40; a circuit holder 50; a casing 60; a base (not depicted); a reflector 480 for diffusing light emitted by the semiconductor light-emitting module 10; and a secondary reflector 490.

As shown in FIG. 16, the reflector 480 includes a main body 481 and an attachment 482. The secondary reflector 490 is attached to the upper surface of the attachment 482 with an engaging mechanism or adhesive. The main body 481 of the reflector 480 has the same structure as the main body 81 of the reflector 80 pertaining to Embodiment 1, whereas the attachment 482 has a slightly different structure than the attachment 82 of the reflector 80 pertaining to Embodiment 1.

Specifically, it is the same as the attachment 82 pertaining to Embodiment 1 that the lower surface of the attachment 482 is provided with the protrusion 484 that is to be fit into the cut 18 of the mounting board 11. The difference is that the attachment 482 is provided with a hole 487 that is substantially circular and is located substantially in the middle of the attachment 482. Through the hole 487, the space within the circuit holder 50 is in communication with the space enclosed by a lid 58. Hence, part of the circuit unit 40, which is originally required to be housed within the circuit holder 50, can be housed within the hole 487 and the secondary reflector 490. Also, due to the hole 487, the reflector 480 will not be a hindrance in housing the circuit unit 40. Note that in the present embodiment, the connector 17 of the semiconductor light-emitting module 10 is provided on the upper surface of the tongue-shaped part 16 of the mounting board 11, instead of on the lower surface.

The secondary reflector 490 includes: a main body 491 that is in a substantially cylindrical shape; and a lid 492 that is in a cap-like shape and covers the upper opening of the main body 491. The inside diameter of the main body 491 is constant, whereas the outside diameter of the top part of the main body 491 gradually increases from bottom to top. The outer surface of the main body 491 entirely serves as a reflective surface. The reflective surface includes: a first reflective surface 493 that is the outer surface of the part with the constant outside diameter of the main body 491 and whose vertical cross section is in a straight shape that is in parallel with the lamp axis J; and a second reflective surface 494 that is the outer surface of the part with the increasing outside diameter of the main body 491 and whose vertical cross section is in a substantially arc-like shape curving toward the lamp axis J.

As represented as optical paths L3 in FIG. 16, a portion of the light emitted by the semiconductor light-emitting module 10 and having passed through the opening 486 of the reflector 480 is reflected off the first reflective surface 493 of the secondary reflector 490 obliquely upward, and another portion is laterally reflected off the second reflective surface 494 of the secondary reflector 490 in the lateral direction. As described above, the stated structure generates supplementary light travelling along a midway course between the light passing through the opening 486 of the reflector 480 and travelling upward and the light reflected off the reflective surface 485 of the reflector 480 and travelling obliquely downward. Hence, the unevenness in the radiant intensity distribution hardly occurs, and the light source 400 exhibits particularly excellent luminous intensity distribution. Moreover, since a portion of the light emitted by the semiconductor light-emitting module 10 and having passed through the opening 486 of the reflector 480 travels upward instead of striking the first reflective surface 493 and the second reflective surface 494, the light source 100 exhibits excellent appearance during the lighting.

### Embodiment 6

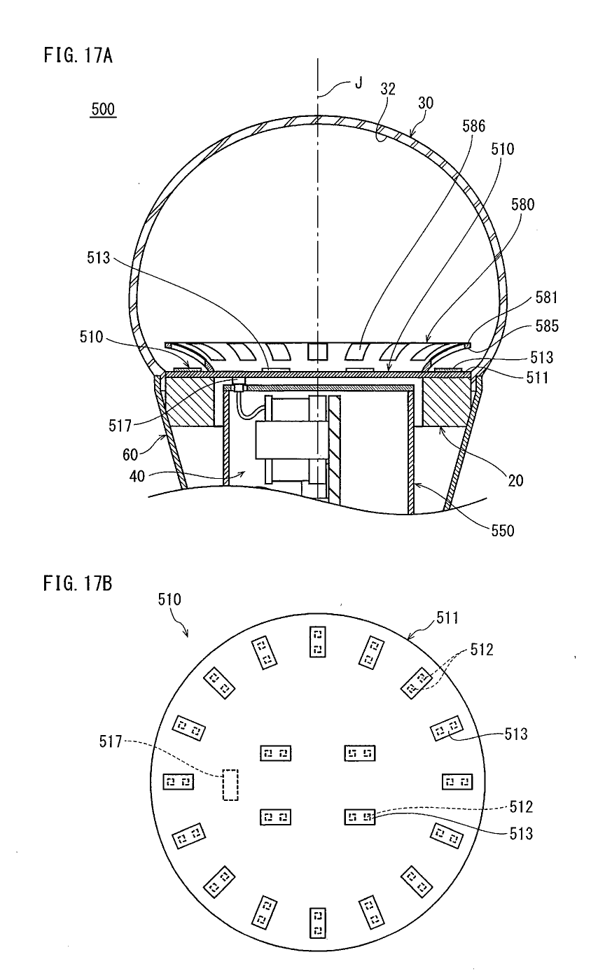

FIGS. 17A and 17B are diagrams for explaining a light source pertaining to Embodiment 6. FIG. 17A is a cross-sectional view showing primary elements of the light source, and FIG. 17B is a plan view showing a semiconductor light-emitting module. As shown in FIG. 17A, a light source 500 pertaining to Embodiment 6 is different from the light source 100 pertaining to Embodiment 2 in that semiconductor light-emitting elements 512 are additionally provided in the area near the lamp axis J on the mounting board 511 of the semiconductor light-emitting module 510. The other components are basically the same as the light source 100 pertaining to Embodiment 2. Therefore, the following describes only the differences in detail, and the explanations of the other components are simplified or omitted. The same components as the embodiments described above are given the same reference numbers as the embodiments.

The light source 500 pertaining to Embodiment 6 is an LED lamp that serves as a substitute for an incandescent light bulb, and includes: a semiconductor light-emitting module 510 as a light source; a mount 20 on which the semiconductor light-emitting module 510 is mounted; a globe 30 covering the semiconductor light-emitting module 510; a circuit unit 40 for lighting the semiconductor light-emitting module 510; a circuit holder 150; a casing 60; a base (not depicted); and a reflector 580 for diffusing light emitted by the semiconductor light-emitting module 510.

As shown in FIG. 17B, the semiconductor light-emitting module 510 has a mounting board 511 that is in a disc-like shape instead of in the annular shape, and the semiconductor light-emitting elements 512 are not only mounted annularly but also mounted inside the ring. Specifically, four pairs of two semiconductor light-emitting elements 512, for example, are arranged in a central area (near the lamp axis J) of the mounting board 511, for example. The four pairs of semiconductor light-emitting elements 512 are located inside the reflector 580. Each pair of the semiconductor light-emitting elements 512 is separately sealed with the sealant 513. Also, a connector 517 is provided on the lower surface of the mounting board 511.

The reflector 580 has a main body 581 that is in a substantially cylindrical shape. Unlike the main body 181 of the reflector 180 pertaining to Embodiment 2, the main body 581 does not have a part 181a with an increasing diameter and a part 181b with a constant diameter. Instead, the diameter of the main body 581 gradually increases from bottom to top along its entire body. The outer surface 585 of the main body 581 entirely serves as a reflective surface, and the vertical cross section thereof is in a substantially arc-like shape curving toward the lamp axis J.

The main body 581 is provided with openings 586 elongated in the direction perpendicular to the cylinder axis thereof. The openings 586 are arranged radially with respect to the cylinder axis. Specifically, in plan view, each of the openings 586 is in a substantially rectangular shape whose lengthwise direction is perpendicular to the lamp axis J. Part of sealants 513, which seal the annularly-arranged semiconductor light-emitting elements 512 of the semiconductor light-emitting module 510, are located within the openings 586 (i.e. can be seen from above the openings 586).

Since the light source 500 pertaining to Embodiment 6 has the stated structure, the light emitted by the semiconductor light-emitting elements 512 arranged inside the reflector 580 travels upward with almost no interference by the reflector 580. The amount of light travelling upward can be thus increased, and the reflector 580 casts less shadow.

### <Modifications>

Although the structure of the present invention has been described above based on Embodiments 1 through 6, the present invention is not limited to these embodiments. For example, Part of the structures of the light sources pertaining to Embodiments 1 through 6 and the structures pertaining to the following modifications may be combined according to needs. Also, the materials, numerical values or the likes suggested above are merely preferable values, and the present invention is not limited by them. The structure of the light source may be modified according to needs within the scope of the technical concept of the present invention.

For example, the semiconductor light-emitting module pertaining to the present invention may be provided with only one semiconductor light-emitting element, instead of with a plurality of semiconductor light-emitting elements.

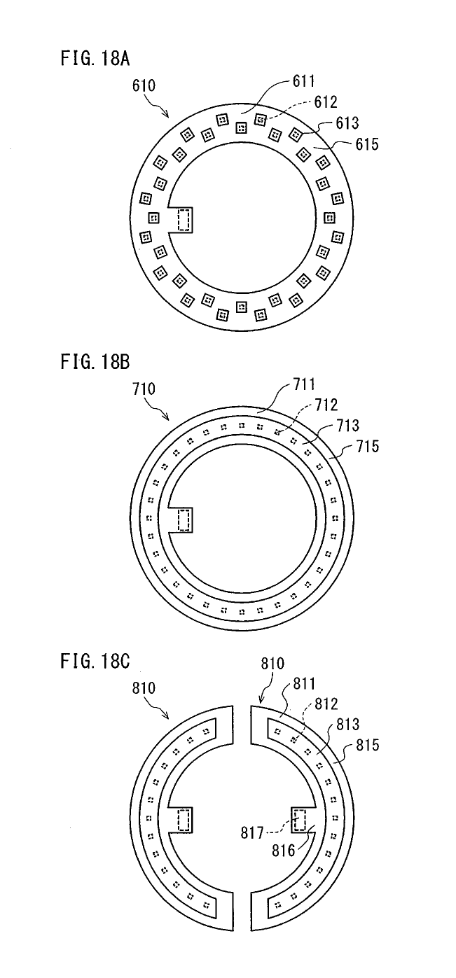

Also, as with the semiconductor light-emitting module 610 shown in FIG. 18A, a plurality of semiconductor light-emitting elements 612 may be disposed on the element mounting part 615 of the mounting board 611 in a staggered arrangement along the circumference of the element mounting part 615. Each of the semiconductor light-emitting elements 612 is separately sealed with the sealant 613, for example. With such a structure, the part that emits light can be uniformly formed on the element mounting part 615, and improves the luminous intensity distribution.

Also, as with the semiconductor light-emitting module 710 shown in FIG. 18B, a plurality of semiconductor light-emitting elements 712 may be disposed on the element mounting part 715 of the mounting board 711 along the circumference of the element mounting part 715, and all the semiconductor light-emitting elements 712 may be sealed with a single sealant 713 that is in a substantially annular shape.

With such a structure, the parts that emit light can be arranged at consecutive locations along the circumference of the element mounting part 715, and the unevenness in the luminance in the circumferential direction hardly occurs. This structure is compatible with the reflector 280 pertaining to Embodiment 3 with which the openings 286 elongated in the circumferential direction of the main body 281, and it is completely unnecessary to correct positioning of the openings 286 and the sealants 213 in the circumferential direction. Hence, it is even easier to assemble the light source 200.

Furthermore, as with the semiconductor light-emitting modules 810 shown in FIG. 18C, a plurality of separate semiconductor light-emitting modules 810 may be mounted on the mount 20. In this example, the mounting board 811 is composed of: an element mounting part 815 that is in a substantially arc-like shape; and a tongue-shaped part 816 that protrudes from a portion of the element mounting part 815. A plurality of semiconductor light-emitting elements 812 are arranged on the element mounting part 815 in an arc-like pattern, and these semiconductor light-emitting elements 812 are sealed with a single sealant 813 that is in an arc-like shape. Also, a connector 817 is disposed on the tongue-shaped part 816. Even with such a structure, assembling work will not be complicated if the semiconductor light-emitting modules 810 can be mounted on the upper surface 22 of the mount 20, i.e., can be mounted on a same plane.

The following describes modifications relating to the globe 30 pertaining to the present invention. In the globe 30, the area that light reaches after being reflected off the reflector 80 obliquely downward so as to avoid the upper surface 22 of the mount 20 (i.e. the area 34 shown in FIG. 2, which is hereinafter referred as “near-opening area 34”) may have been subject to light diffusion treatment so that the area diffuses light more effectively.

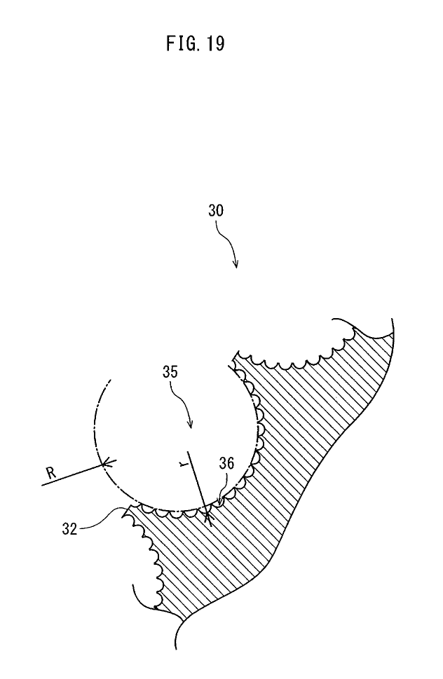

FIG. 19 is a diagram for explaining light diffusion treatment applied on a globe pertaining to a modification. FIG. 19 simply shows a cross section of the near-opening area 34 of the globe 30 in a plane including the lamp axis J.

In the near-opening area 34 on the inner circumferential surface 32 of the globe 30, a plurality of first concavities 35, each in a hemispherical shape with radius R (e.g. R=40 μm), are formed evenly. Also, on the inner surface of each first concavity 35, a plurality of second concavities 36, each in a hemispherical shape with radius r smaller than R (e.g. r=5 μm), are formed evenly. Note that the radius R of the first concavities 35 is preferably in the range of 20≦R≦40, and the radius r of the second concavities 36 is preferably in the range of 2≦r≦8.

With the stated double-dimple structure, in which each of evenly-formed concavities (dimples) have even smaller concavities (dimples) therein, the globe 30 (the near-near opening area 34) diffuses the light travelling obliquely downward so as to avoid the upper surface 22 of the mount 20 after being reflected off the outer surface 85. This further widens the luminous intensity distribution angle downward.

In particular, when the double-dimple structure is formed only in the near-opening area 34, portions of light other than the portion reflected obliquely downward, such as portions of light travelling upward or in the lateral direction, can be efficiently taken out of the globe 30 without being lost at the globe 30.

Although the semiconductor light-emitting elements are assumed to emit the light upward, namely in the direction of the lamp axis J, some or all of the semiconductor light-emitting elements may be tilted with respect to the lamp axis J. Such a structure further improves the light distribution controllability, and realizes desirable light distribution.

### INDUSTRIAL APPLICABILITY

The present invention is broadly applicable to common lighting systems.

### REFERENCE SIGNS LIST

1, 100, 200, 300, 400, 500: Light source
12, 212, 512, 612, 712, 812: Semiconductor light-emitting elements
18: Inner surfaces
20: Mount
21: Through hole
22: Upper surface
30: Globe
35, 36: Concavity
40: Circuit unit
50, 150: Circuit holder
55: Outer surface
80, 180, 280, 380, 480, 580: Reflector
81, 181, 281, 381, 481, 581: Main body
181a, 281a, 381a: Part with gradually increasing diameter
85, 185, 285, 385, 485, 585: Reflective surface
86, 186, 286, 486, 586: Openings
386: cuts
490: Secondary reflector
493,494: Reflective surface

1. A light source for illumination, comprising:
a mount;
a plurality of semiconductor light-emitting elements arranged on an upper surface of the mount so that each semiconductor light-emitting element emits light primarily upward; and
a reflector located above the semiconductor light-emitting elements and having a reflective surface configured to reflect a portion of primary light from the semiconductor light-emitting elements obliquely downward so that the portion of the primary light is prevented from striking the upper surface of the mount, wherein
the semiconductor light-emitting elements are annularly arranged on the upper surface of the mount,
the reflective surface of the reflector is annularly shaped to face the semiconductor light-emitting elements,
the portion of the primary light reflected off the reflective surface passes through an annular area laterally surrounding the mount, and
the reflector is provided with an opening or a cut for leaking another portion of the primary light upward.

2. (canceled)

3. The light source of claim 1, wherein
the reflector includes a main body that is tubular,
a tube axis of the main body is perpendicular to the upper surface of the mount,
an outside diameter of at least a portion of the main body gradually increases from bottom to top,
the portion of the main body covers the semiconductor light-emitting elements, and
at least an outer circumferential surface of the portion of the main body is included in the reflective surface.

4. The light source of claim 3, wherein
the outer circumferential surface of the portion of the main body is a concave surface curving toward the tube axis.

5. The light source of claim 3, wherein
the opening or the cut is provided at least in the main body.

6. The light source of claim 5, wherein
the opening or the cut is provided in a plurality, and
the openings or the cuts are arranged at intervals along a circumference of the main body around the tube axis.

7. The light source of claim 6, wherein
the openings or the cuts are each elongated in a direction that is perpendicular to the tube axis of the main body, and are arranged radially with respect to the tube axis.

8. The light source of claim 6, wherein
the openings or the cuts are each elongated along the circumference of the main body so as to be in an annular shape or an arc-like shape, and are arranged around the tube axis.

9. The light source of claim 1, further comprising:
a secondary reflector configured to reflect, in a lateral direction, a portion of the primary light that has passed through the opening or the cut.

10. The light source of claim 1, wherein
the mount is provided with a through hole extending upward, and at least a portion of a circuit unit is located within the through hole, the circuit unit causing the semiconductor light-emitting elements to emit light.

11. The light source of claim 10, wherein
the circuit unit is housed in a circuit holder, and a gap is provided between an outer surface of the circuit holder and an inner surface of the through hole in the mount.

12. The light source of claim 1, further comprising:
a globe covering the reflector, wherein
a portion of the globe that is reached by the portion of the primary light is more light-diffusive than the rest of the globe.

13. (canceled)

14. The light source of claim 12, wherein
an inner circumferential surface of the portion of the globe is provided with a plurality of concavities, and an inner surface of each concavity is furthermore provided with a plurality of concavities.

15. The light source of any of claim 1, wherein
some or all of the semiconductor light-emitting elements are tilted with respect to a lamp axis.
